(19) United States
(12) Patent Application Publication
(10) Pub. No.: US 2010/0304976 A1
(43) Pub. Date: Dec. 2, 2010

(54) ELECTROMAGNET WITH LAMINATED FERROMAGNETIC CORE AND SUPERCONDUCTING FILM FOR SUPPRESSING EDDY MAGNETIC FIELD

(75) Inventors: Johannes Adrianus Overweg, Hamburg (DE); Holger Timinger, Hamburg (DE); Bernd David, Hamburg (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/808,411

(22) PCT Filed: Dec. 19, 2008
(86) PCT No.: PCT/IB2008/055445

§ 371 Date: Jun. 16, 2010

(30) Foreign Application Priority Data
Dec. 21, 2007 (EP) 07123939.6

(51) Int. Cl. H01F 6/00; H01F 3/02; H01L 39/02; G01R 33/035

(52) U.S. Cl. 505/162; 335/297; 335/216; 505/211

(57) ABSTRACT

An electromagnet comprises: a ferromagnetic core (50, 72); electrically conductive windings (34, 76) disposed around the ferromagnetic core such that current flowing in the windings magnetizes the ferromagnetic core; and a superconducting film (60, 80, 82) arranged to support eddy current cancelling supercurrent that suppresses eddy current formation in the ferromagnetic core when the windings magnetize the ferromagnetic core. A magnetic resonance scanner embodiment includes a main magnet (20) generating a static magnetic field and a magnetic field gradient system (30) with a plurality of said electromagnets (34, 50, 60) configured to superimpose selected magnetic field gradients on the static magnetic field.

### FIELD OF THE INVENTION

The following relates to magnetic resonance and related arts. The following finds illustrative application to magnetic resonance scanners, and is described with particular reference thereto. However, the following will find application in other applications employing electromagnets or magnetized ferromagnetic structures.

### BACKGROUND OF THE INVENTION

An electromagnet includes a ferromagnetic core and electrically conductive windings encircling the ferromagnetic core such that current flowing through the electrically conductive windings magnetizes the ferromagnetic core. The electromagnet can provide a dynamically changeable magnetic field whose polarity and field strength depends (neglecting any hysteresis or residual magnetization effects) on the direction and magnitude of electrical current flow through the electrically conductive windings. The ferromagnetic core is made of a ferromagnetic material that includes domains of aligned electron spins that align in the presence of the magnetic field generated by the conductive windings to greatly reinforce or enhance the driving magnetic field, thus enabling efficient generation of large magnetic fields with relatively low electrical current.

Electromagnets find widespread applications in electrical, electromagnetic, electro-mechanical, and other systems and methods. One such application is described in Overweg, International patent application WO 2005/124381 A2 published Dec. 29, 2005, which relates to magnetic resonance scanners employing electromagnets to magnetize ferromagnetic cores that superimpose selected magnetic field gradients on a static (B0) magnetic field (also called main magnetic field) in an examination region of the scanner. Another illustrative application is a power inductor, which comprises an electromagnet operated in a.c. (alternating current) mode.

In an electromagnet, the ferromagnetic material can be a ferromagnetic metal such as steel, usually formed as a rod, bar, or other elongated element having elongation in the direction of magnetization. Using a bulk steel core or other continuous ferromagnetic material can be problematic, because such a structure is strongly supportive of eddy currents, that is, induced electrical current flow loops that produce heat dissipation and contribute to losses and reduced electrical power to magnetic field conversion efficiency. To suppress eddy currents, it is known to use stacked ferromagnetic laminations to form the ferromagnetic core, the laminations assisting in breaking up eddy currents.

However, if the core is not closed in itself, the magnetic flux diverges at the ends and as a result eddy currents can be induced within the plane of a lamination. In the case of a magnetic resonance scanner of the type disclosed in the document WO 2005/124381 A2, the eddy currents flowing within laminations can be large enough to cause unacceptably large dissipation. Eddy currents are most problematic near the ends of the core where the magnetic field diverges and deviates substantially from the intended magnetization direction along the direction of elongation of the ferromagnetic bar.

Accordingly, there remains an unfulfilled need in the art for improved iron-cored electromagnets intended for magnetic field generation, magnetic energy storage, and the like that overcome the aforementioned deficiencies and others.

### SUMMARY OF THE INVENTION

In accordance with certain illustrative embodiments shown and described as examples herein, an electromagnet is disclosed, comprising: a laminated ferromagnetic core; electrically conductive windings disposed around the ferromagnetic core such that current flowing in the electrically conductive windings generates a magnetic field in the ferromagnetic core; and a superconducting film arranged such that induced currents in the superconducting film suppress the component of the magnetic field normal to the laminations of the ferromagnetic core, with the objective to suppress the generation of eddy currents in the ferromagnetic core laminations when the electrically conductive windings magnetize the ferromagnetic core.

In accordance with certain additional illustrative embodiments shown and described as examples herein, a magnetic resonance scanner is disclosed including a main magnet generating a static magnetic field, and a magnetic field gradient system with a plurality of electromagnets as set forth in the immediately preceding paragraph configured to superimpose selected magnetic field gradients on the static magnetic field.

In accordance with certain illustrative embodiments shown and described as examples herein, a magnetic resonance scanner is disclosed, comprising: a main magnet configured to generate a static magnetic field in an examination region; and a magnetic field gradient system arranged to superimpose magnetic field gradients on the examination region, the magnetic field gradient system including a plurality of electromagnets each having a ferromagnetic core on which a superconducting film is disposed to support eddy current-cancelling supercurrent. A supercurrent is a superconducting current, that is, electric current which flows without dissipation in a superconductor.

In accordance with certain illustrative embodiments shown and described as examples herein, an a.c. magnetic field generating method is disclosed, comprising: energizing an electromagnet including a laminated ferromagnetic core to generate a magnetic field in the ferromagnetic core; and inducing current in a superconducting layer arranged parallel with laminations of the laminated ferromagnetic core to cancel the component of the magnetic field in the ferromagnetic core that is oriented perpendicular to the laminations, which would otherwise produce eddy current in the ferromagnetic core.

One advantage resides in reduced electromagnet heating.

Another advantage resides in improved magnetic field gradient quality in a magnetic resonance scanner.

Still further advantages of the present invention will be appreciated by those of ordinary skill in the art upon reading and understand the following detailed description.

### BRIEF DESCRIPTION OF THE DRAWINGS

These and other aspects will be described in detail hereinafter, by way of example, on the basis of the following embodiments, with reference to the accompanying drawings, wherein:

FIG. 1 diagrammatically shows a magnetic resonance scanner in perspective view (top) and in partial cutaway perspective view (bottom); and

FIG. 2 diagrammatically shows a bar type electromagnet including a superconducting film arranged to support eddy current-preventing supercurrent.

Corresponding reference numerals when used in the various figures represent corresponding elements in the figures.

### DETAILED DESCRIPTION OF EMBODIMENTS

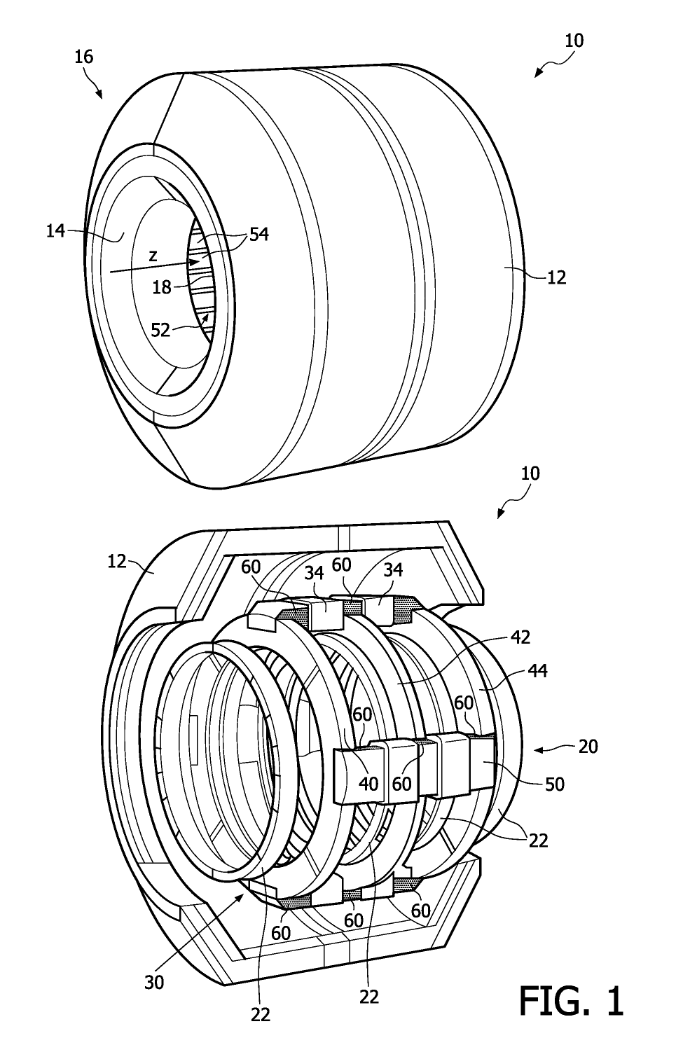

With reference to FIG. 1, a magnetic resonance scanner 10 includes a housing made up of an outer flux return shield 12 and an inner bore tube 14. FIG. 1 shows the magnetic resonance scanner 10 in perspective view (top) and in partial cutaway perspective view (bottom). In the cutaway view, the inner bore tube 14 and a portion of the outer flux return shield 12 are removed to reveal selected internal components.

The outer flux return shield 12 and the inner bore tube 14 are sealed together to define a vacuum jacket. The inside of the inner bore tube 14 is an examination region 18 in which a subject is disposed for magnetic resonance imaging, magnetic resonance spectroscopy, or the like. A main magnet 20 is disposed inside of the vacuum jacket 16 surrounding the bore tube 14. The main magnet 20 includes a plurality of spaced apart generally annular magnet windings sections 22, six sections in the embodiment of FIG. 1. Each windings section 22 includes a number of turns of an electrical conductor, preferably a superconductor. The illustrated main magnet 20 is closer to the bore tube 14 than to the flux return shield 12. Although six windings sections 22 are included in the embodiment of FIG. 1, the number of annular magnet winding sections 22 can vary. The windings sections 22 of the main magnet 20 are designed in conjunction with the flux return shield 12 using electromagnetic simulation, modeling, or the like to produce a substantially spatially uniform magnetic field in the examination region 18 in which the main magnetic field vector is directed along an axial or z direction parallel to the axis of the bore tube 14. The bore tube 14 is made of a non magnetic material; however, the outer flux return shield 12 is made of a ferromagnetic material and provides a flux return path for completing the magnetic flux loop. That is, magnetic flux generated by the main magnet 20 follows a closed loop that passes through the inside of the bore tube 14 including the examination region 18 and closes back on itself by passing through the flux return shield 12. As a result, there exists a low magnetic field region within the vacuum jacket 16 between the magnet 20 and the flux return shield 12. In the embodiment of FIG. 1, the flux return shield 12 also serves as the outer portion of the vacuum jacket 16; however, in other embodiments a separate flux return shield can be provided.

A magnetic field gradient system 30 is disposed in the low magnetic field region existing outside the magnet 20 and inside the flux return shield 12. The magnetic field gradient system 30 includes a plurality of magnetic field gradient coils 34 wrapped around ferromagnetic crossbars 50 which are arranged generally parallel to the axis of the magnet. In the illustrated embodiment, the magnetic field gradient system 30 includes three ferromagnetic rings 40, 42, 44 disposed between the generally annular magnet windings sections 22 but these may be omitted. The magnetic field gradient coils 34 include wire turns or other electrical conductors transverse to the crossbars 50. The ferromagnetic crossbars 50 and conductive windings 34 define electromagnets that generate magnetic field gradients superimposed on the uniform field generated by the main field magnet 20. The magnetic field gradient system 30 is structurally bilaterally symmetric, with the same plane of bilateral symmetry as the main magnet 20. The illustrated magnetic field gradient system 30 has a four fold rotational symmetry provided by arrangement of four crossbars 50 at 90o annular intervals. Each crossbar 50 includes magnetic field gradient coils 34 wrapped on either side of the plane of bilateral symmetry. The number of crossbar/gradient coil units 34, 50 may also be increased to a greater number, preferably an integer multiple of 4, distributed with equal angle increment about the symmetry axis of the magnet 20.

An RF transmit/receive coil 52 supported by the bore tube 14 includes a plurality of strip line conductors 54 disposed on a surface of the bore tube 14 outside of the vacuum jacket 16. The strip line conductors are connected with a current flow return path (not shown) such as a transverse conductive ring to form a birdcage coil or a surrounding cylindrical radio frequency shield to form a transverse electromagnetic (TEM) coil. The conductors 54 can be variously embodied as printed circuitry disposed or printed onto the electrically non conducting bore tube 14, or disposed or printed on separate printed circuit boards or an inner bore liner secured to the bore tube 14, or formed as foil strips which are adhered to the bore tube 14. A radio frequency shield or screen (not shown) is disposed around the radio frequency coil 52, for example on the vacuum side of the bore tube 14 or on the inner surface of the cylinder supporting the main field magnet 20.

Additional information on the magnetic resonance scanner 10 thus far described may be found in Overweg, U.S. patent application 2007/0216409 A1 published Sep. 20, 2007 and in Overweg, International patent application WO 2005/124381 A2 published Dec. 29, 2005. The scanner 10 is modified as compared with scanners of the above references in that the electromagnets defined by the ferromagnetic crossbars 50 and conductive windings 34 include superconducting films 60 disposed on or located in close proximity to surfaces of the crossbars 50. As described herein, such superconducting films 60 advantageously support supercurrent that flows to generate a magnetic field that cancels a magnetic field component in the ferromagnetic crossbar 50 oriented transverse to the superconducting film 60, which transverse magnetic field in the crossbar 50 if not so canceled would otherwise generate eddy current in the laminations of the ferromagnetic crossbar 50.

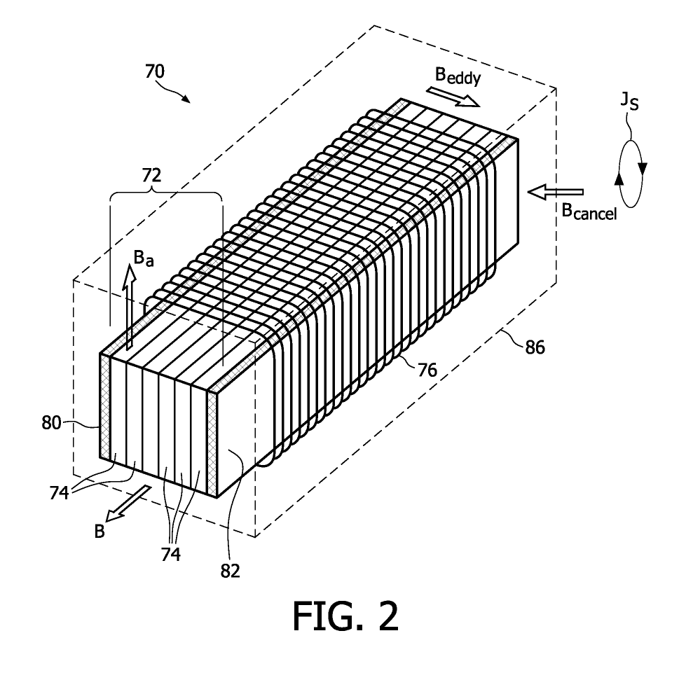

With reference to FIG. 2, a bar type electromagnet 70 is suitable for use in substantially any application employing a bar-type electromagnet, such as in the magnetic field gradient system 30 of the magnetic resonance scanner 10 of FIG. 1. The electromagnet 70 includes a bar type ferromagnetic core 72 formed as a stack of ferromagnetic laminations 74 made of a ferromagnetic material such as steel or a high permeability nanocrystalline ferromagnetic material such as Finemet® (available from Hitachi Metals, Tokyo, Japan). Materials of the latter type have certain advantages relating to higher permeability and lower losses as compared with equivalent ferromagnetic cores made of steel materials. Electrically conductive windings 76 are disposed around the ferromagnetic core 72 such that current flowing in the electrically conductive windings 76 magnetizes the ferromagnetic core to generate a magnetic field B directed generally along a direction of elongation of the bar type ferromagnetic core 72. Depending upon the direction of current flow in the electrically conductive windings 76, the magnetic field B may be of either the same or opposite polarity compared with the direction illustrated in FIG. 2. If the current in the electrically conductive windings 76 is turned off completely, then the magnetic field B will go to substantially zero amplitude (neglecting any hysteresis or residual magnetization in the ferromagnetic core 72).

The linear solenoidal configuration of the electrically conductive windings 76 and the elongate bar type shape of the ferromagnetic core 72 combine to ensure that the magnetic field B induced in the ferromagnetic core 72 is substantially as shown, that is, parallel with the direction of elongation of the ferromagnetic core 72. However, some magnetic field components will appear which are transverse to the direction of elongation. This is most predominant at the ends of the bar type ferromagnetic core 72. In FIG. 2, a transverse magnetic field component Bₐ is shown, which is transverse to the direction of elongation of the ferromagnetic core 72 but parallel with the ferromagnetic laminations 74. Because the magnetic field component Bₐ is parallel with the ferromagnetic laminations 74, it is not capable of inducing substantial eddy currents in the ferromagnetic laminations 74. Indeed, this is an advantage of using laminations.

However, as further shown in FIG. 2, another transverse magnetic field component B_{eddy} will appear, predominantly at the ends of the ferromagnetic core 72, which is transverse both to the direction of elongation of the ferromagnetic core 72 and to the ferromagnetic laminations 74. Because the magnetic field component B_{eddy} is transverse to the ferromagnetic laminations 74, it can induce eddy currents in the ferromagnetic laminations 74. Such eddy currents dissipate resistively as heat, which has to be removed from the ferromagnetic core 72 by some form of active or passive cooling. This heat is especially troublesome if the magnetic field generating device is to operate at a temperature far below room temperature. The superconducting MRI magnet/gradient system is an example of such a low temperature application.

As further shown in FIG. 2, the electromagnet 70 includes superconducting films 80, 82 disposed on or located in close proximity to the two outermost laminations of the stack of laminations 74 making up the ferromagnetic core 72. The superconducting films 80, 82 may, for example, correspond to the superconducting films 60 on the ferromagnetic cores of the electromagnets of the magnetic field gradient system 30 of the magnetic resonance scanner 10 of FIG. 1. The superconducting films 80, 82 are made of a superconducting material in a superconducting phase or state that supports the flow of supercurrent. A supercurrent is a superconducting current, that is, electric current which flows without dissipation in a superconductor. Attempting to impose a magnetic field directed perpendicular to the surface of a superconductor causes a supercurrent to flow that generates a magnetic field cancelling out or substantially cancelling out the normal component of the magnetic field that would otherwise penetrate the superconductor.

These properties can be applied to the electromagnet 70 of FIG. 2 as follows. When the electromagnet 70 is energized, it would generate the magnetic field B_{eddy} in the absence of the superconducting films 80, 82, and the magnetic field B_{eddy} in turn would generate power dissipating eddy currents in the ferromagnetic laminations 74. However, the electromagnet 70 does include the superconducting films 80, 82, which compensates the magnetic field B_{eddy} by means of the induced supercurrent J_{S} flowing in the plane of the superconducting film 82 (and, although not expressly illustrated, also in the plane of the superconducting film 80). The net magnetic field transverse to the ferromagnetic laminations 74 existing in the ferromagnetic laminations 74 is therefore, to first approximation, B_{eddy}+B_{cancel}=0. As the net magnetic field transverse to the ferromagnetic laminations 74 is zero, it follows that no significant eddy current is generated in the planes of the ferromagnetic laminations 74. Since the dissipation is proportional to the square of the current density of the eddy currents, the reduction of the amplitude of the eddy currents in the laminations 74 greatly reduces the dissipation.

The superconducting films 80, 82 can be made of any suitable superconductor. For engineering convenience, a high temperature superconductor such as yttrium barium copper oxide (YBCO, e.g. Yba2Cu3O7-□) is advantageous. A superconducting material can only support supercurrent when it is in the superconducting state, which is achieved below a critical temperature that decreases as the magnitude of supercurrent increases. A high temperature superconducting material such as YBCO has a critical temperature for low supercurrent magnitudes that is above or comparable to the 77K boiling point for liquid nitrogen. For example, YBCO exhibits a high critical temperature for low supercurrent magnitude of about 95K. To keep the superconducting films 80, 82 below the critical temperature for the superconducting phase transition, a cryostat 86 (diagrammatically shown in phantom in FIG. 2) suitably encompasses the electromagnet 70. While YBCO is mentioned as a suitable illustrative superconducting material, other high temperature superconducting materials such as certain other cuprate materials may also be used for the superconducting films 80, 82. Still further, while high temperature superconducting materials have practical advantages, it is also contemplated for the superconducting films 80, 82 to be made of low or intermediate temperature superconducting materials, with the cryostat 86 being selected to provide suitably low temperature to maintain superconductivity.

In FIG. 2, the superconducting films 80, 82 are substantially coextensive with the exposed principal surfaces of the two outermost laminations of the stack of ferromagnetic laminations 74. However, since most eddy currents are formed at or near the ends of the bar type ferromagnetic core 72, in some embodiments the superconducting films are contemplated to be disposed only near the ends of the outermost ferromagnetic laminations. In other contemplated embodiments, only one of the two superconducting films 80, 82 may be provided.

The illustrated superconducting films 80, 82 are coated, deposited, adhered, or otherwise formed on or attached to the exposed principal surfaces of the outermost ferromagnetic laminations. However, other arrangements of superconducting films that are parallel with the ferromagnetic laminations 74 are also suitable. For example, the superconducting films can be disposed on a surface parallel with the laminations 74 and close to the ferromagnetic core 72. It is also contemplated to interleave one or more superconducting films between neighboring ferromagnetic laminations of the stack of ferromagnetic laminations 74.

In order to keep the superconducting films at a sufficiently low temperature, they are thermally connected to a refrigeration system which may be identical to the refrigeration system cooling the main magnet 20. In order to extract the heat from the superconducting layer in an efficient way, the layer is preferably in intimate thermal contact with a substrate (not shown) with good thermal conductivity. Such a substrate may be made from a metal such as copper or from a ceramic material with good thermal conductivity. If the cooling substrate is electrically conducting but not superconducting, it has to be located at the side of the superconducting film not facing the ferromagnetic core 72, in order to prevent that dissipating currents are induced in the cooling substrate. The cooling substrate is thermally connected to the refrigerator by means of heat transporting members such as copper busbars or copper braids. Alternatively, the cooling of the superconducting layers may be accomplished by circulation of cold gas or by heat pipes in which condensation and evaporation of a liquid serves as a heat transfer mechanism. Since the ferromagnetic core 72 will exhibit some degree of a.c. field induced heating, there is preferably a thin thermally insulating layer between the surface of the ferromagnetic core 72 and the superconducting film. This thermally insulating layer should be sized such that at the expected equilibrium temperature of the ferromagnetic core 72, the temperature of the superconducting film can be kept below the transition temperature of the superconductor above which the superconducting film would no longer be capable of sustaining the required shielding current.

The supercurrent induced in the superconducting films 80, 82 will lead to magnetic forces due to the magnetic field emanating from the ferromagnetic core 72. The direction of these forces is such that the superconducting film is pushed away from the surface of the ferromagnetic core 72. A suitably designed mechanical support structure for the superconducting films should be provided to ensure that the superconducting films 80, 82 remain in position in contact with or at a short distance from the ferromagnetic core 72. For example, a mechanical clamping construction (not shown) may be separate from or integrated with the structures required for keeping the superconducting films 80, 82 at their operating temperature. The mechanical support of the superconducting films may also be an integral part of the structure holding the magnetizing coils 34 in position relative to the ferromagnetic core 72.

The illustrated superconducting films 80, 82 are illustrated as continuous films. However, it is also contemplated to have slits, holes, or other discontinuities in the superconducting films, so long as the discontinuities are not substantial enough to prevent flow of the eddy current-cancelling supercurrent J_{S} in the superconducting films. The superconducting film may be slit purposely in a pattern such that the slit lines are parallel to the direction of the induced supercurrent, which would cancel out the normal component of the magnetic field emanating from the ferromagnetic core 72. Such a slitting pattern would have the advantage that it would prevent other current patterns from being induced. Such a slitting pattern would transform the superconducting film into an assembly of nested, shorted superconducting windings. A further modification of the concept would be to open up each of the thus obtained windings and connect these in series to form a fingerprint-shaped planar superconducting coil. As used herein, the term “superconducting film” is intended to encompass such a fingerprint-shaped planar superconducting coil, or other generally planar superconducting structures. The aforementioned superconducting coil could be shorted in itself and the current flowing in it would be proportional to the magnitude of the perpendicular field emanating from the ferromagnetic core 72. The superconducting surface coil could also optionally be driven by an active current source located outside the magnetic field generating device. If the superconducting film is subdivided into individual windings in such a way that the operating current in each of the nested turns is equal to the current in the magnetizing coils 34, the drive coils and the superconducting surface films 80, 82 defining superconducting coils can be connected in series to ensure that the currents remain equal under all operating conditions. By doing so, the magnetizing coils and the surface coils 80, 82 have been combined into one single complex field generating coil with the property that the ferromagnetic core 72 is magnetized in the elongation direction while at the same time suppressing the component of the field perpendicular to the laminations. The design problem of how to shape the windings of such a complicated magnetizing and shielding coil is analogous to the problem of designing an actively shielded gradient coil as is commonly used in magnetic resonance imaging systems.

Additionally, if the superconducting films are not shaped in the form of actively driven discrete windings, it is contemplated for the superconducting films 80, 82 to include dispersed normal regions (not illustrated) preferably in the form of narrow slits bridged by a resistive conductor such as copper, in order to suppress persistent supercurrent. If so provided, the dispersed normal regions should be such as to allow formation and dissipation of the eddy current-cancelling supercurrent J_{S} at rates sufficient to track the operational frequency or rate of change of the magnetic field B. In the magnetic resonance scanner embodiment of FIG. 1, for example, the superconducting layers 60 are optionally designed using distributed normal regions, in order to provide sufficient residual surface resistance so that its electrical time-constant is of the order of 1 100 seconds. Any d.c. (direct current) currents trapped inside the superconducting layers 60 will then decay, so that the static homogeneity of static (B0) magnetic field generated by the main magnet 20 is not impaired.

With brief reference back to the magnetic resonance scanner 10 of FIG. 1, the electromagnets are suitably cooled in order to maintain the superconducting state for the superconducting films 60 by using the same cryostat as is used to cool the generally annular magnet windings sections 22. The outer flux return shield 12 and the inner bore tube 14 are sealed together to define a vacuum jacket. Although this jacket is not illustrated in detail in FIG. 1, the vacuum jacket can have multiple layers including one or more cooling layers or regions containing a cryogenic fluid or fluids such as liquid nitrogen or liquid helium, and an encompassing vacuum layer or region providing thermal isolation for the cryogenic layers. Thus, cooling the superconducting films 60 does not entail adding substantial cryogenic hardware to the magnetic resonance scanner 10.

The techniques disclosed herein for suppressing eddy currents can be used in other applications, such as in a power inductor having an open loop ferromagnetic core made up of a stack of ferromagnetic laminations formed of steel or another ferromagnetic metal, or of a high permeability nanocrystalline ferromagnetic material such as Finemet®. Electrically conductive windings in such a power inductor are energized by applying an a.c. primary voltage across terminals of the windings such that the combination of the open loop ferromagnetic core and the primary windings act as an electromagnet. The purpose of such a device can be to generate a suitably shaped a.c. magnetic field between the ends of a ferromagnetic core which can be used for various applications. In this case, the ends of the ferromagnetic core can be shaped such as to assist in defining the shape of the usable magnetic field. Possible applications include in equipment for charged particle steering, electro-magnetic heating, magneto-forming, magnetic propulsion, magnetic separation, and so forth. A power inductor can also be used as a low-loss reactive load in high current circuits, for example to suppress surges in electric power distribution systems. In such power inductors, there is again the possibility of generating an inadvertent magnetic field B_{eddy} oriented transverse to the ferromagnetic laminations, which would produce energy dissipating eddy currents. Indeed, eddy current losses in power inductors are a known factor adversely impacting their efficiency. To suppress eddy current, superconducting layers are suitably disposed on or proximate to the exposed principal surfaces of the outermost ferromagnetic laminations of the stack of ferromagnetic laminations of the power inductor, so as to support eddy current-cancelling supercurrent.

The illustrated superconducting films 60, 80, 82 are expected to be substantially effective in suppressing eddy currents in the associated electromagnets. However, other measures may optionally be taken to further suppress eddy currents. For example, the use of ferromagnetic laminations 74 to further suppress eddy currents has already been illustrated. Another measure optionally includes adjusting the electrically conductive windings near the ends of the bar type ferromagnetic core to reduce the magnetic field B_{eddy} oriented to induce eddy current. For example, by determining a priori the magnetic field B_{eddy} oriented to induce eddy current, compensatory electrically conductive windings can be added to correspond to the eddy current-cancelling supercurrent J_{S}. In other words, the superconducting films can be replaced by or supplemented by non superconducting electrically conductive windings that produce a current equivalent to the eddy current-cancelling supercurrent J_{S}.

The illustrated superconducting films 60, 80, 82 are configured to suppress eddy currents. However, superconducting films can be incorporated into electromagnets for other purposes, such as to act as a shield to ensure stray magnetic field is not present coming off of a portion of the electromagnet that faces a magnetically sensitive component or region.

The invention has been described with reference to the preferred embodiments. Modifications and alterations may occur to others upon reading and understanding the preceding detailed description. It is intended that the invention be construed as including all such modifications and alterations insofar as they come within the scope of the appended claims or the equivalents thereof. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The disclosed method can be implemented by means of hardware comprising several distinct elements, and by means of a suitably programmed computer. In the system claims enumerating several means, several of these means can be embodied by one and the same item of computer readable software or hardware. The mere fact that certain measures are recited in mutually different dependent claims does not indicate that a combination of these measures cannot be used to advantage.

1. An electromagnet comprising:
a laminated ferromagnetic core (50, 72);
electrically conductive windings (34, 76) disposed around the ferromagnetic core such that current flowing in the electrically conductive windings generates a magnetic field (B, Bₐ, B_{eddy}) in the ferromagnetic core; and
a superconducting film (60, 80, 82) arranged parallel with laminations (74) of the laminated ferromagnetic core such that induced current (J_{S}) in the superconducting film suppresses a component (B_{eddy}) of the magnetic field in the ferromagnetic core normal to the laminations of the ferromagnetic core.

2. The electromagnet as set forth in claim 1, wherein the laminated ferromagnetic core (50, 72) is elongated, the electrically conductive windings (34, 76) define electrically conductive loops oriented generally transverse to the direction of elongation of the ferromagnetic core, and the superconducting film (60, 80, 82) is oriented generally parallel with the direction of elongation of the ferromagnetic core.

3. The electromagnet as set forth in claim 2, wherein the superconducting film comprises:
two superconducting films (80, 82) disposed on opposing surfaces of the laminated ferromagnetic core (72).

4. The electromagnet as set forth in claim 1, wherein the superconducting film (60, 80, 82) is disposed on a surface of the laminated ferromagnetic core (50, 72) parallel with the laminations (74).

5. The electromagnet as set forth in claim 1, wherein the electrically conductive windings (34, 76) are disposed around the ferromagnetic core (50, 72) such that current flowing in the electrically conductive windings magnetizes the ferromagnetic core substantially along a direction of magnetization, and the superconducting film (60, 80, 82) is parallel with the direction of magnetization.

6. The electromagnet as set forth in claim 1, wherein the laminations (74) of the laminated ferromagnetic core (50, 72) are formed of a nanocrystalline ferromagnetic material.

7. The electromagnet as set forth in claim 1, wherein the laminated ferromagnetic core (50, 72) comprises a stack of parallel laminations (74) made of nanocrystalline ferromagnetic material, and the superconducting film (60, 80, 82) comprises two superconducting films (80, 82) disposed on opposite sides of the stack.

8. The electromagnet as set forth in claim 1, wherein the superconducting film (60, 80, 82) includes dispersed normal regions effective to suppress persistent supercurrent.

9. A magnetic field gradient system (30) for a magnetic resonance scanner (10), the magnetic field gradient system including a plurality of electromagnets (34, 50, 60) as set forth in claim 1.

10. A magnetic resonance scanner (10) including a main magnet (20) generating a static magnetic field and a magnetic field gradient system (30) with a plurality of electromagnets (34, 50, 60) as set forth in claim 1 configured to superimpose selected magnetic field gradients on the static magnetic field.

11. The magnetic resonance scanner as set forth in claim 10, further comprising:
a vacuum jacket (12, 14) containing both the main magnet (20) and at least the electromagnets (34, 50, 60) of the magnetic field gradient system (30).

12. An a.c. magnetic field generating method comprising:
energizing an electromagnet (34, 50, 60, 70) including a laminated ferromagnetic core (50, 72) to generate a magnetic field (B, Bₐ, B_{eddy}) in the ferromagnetic core; and
inducing current (J_{S}) arranged parallel with laminations (74) of the laminated ferromagnetic core to cancel the component (B_{eddy}) of the magnetic field in the ferromagnetic core that is oriented perpendicular to the laminations, which would otherwise produce eddy current in the ferromagnetic core.

13. The a.c. magnetic field generating method as set forth in claim 12, wherein the inducing comprises:
inducing current (J_{S}) in a superconducting layer (60, 80, 82) arranged parallel with laminations (74) of the laminated ferromagnetic core to cancel the component (B_{eddy}) of the magnetic field in the ferromagnetic core (50, 72) that is oriented perpendicular to the laminations (74), which would otherwise produce eddy current in the ferromagnetic core.

14. The a.c. magnetic field generating method as set forth in claim 12, wherein the inducing comprises:
determining a priori the component (B_{eddy}) of the magnetic field (B, Bₐ, B_{eddy}) in the ferromagnetic core (50, 72) that is oriented perpendicular to the laminations (74); and
adjusting electrically conductive windings (34, 76) used for the energizing to cancel the component of the magnetic field in the ferromagnetic core that is oriented perpendicular to the laminations.

15. The a.c. magnetic field generating method as set forth in claim 12, further comprising:
generating a main magnetic field, the energizing and inducing being effective to superimpose a selected magnetic field gradient on the main magnetic field.
